(19) United States
(12) Patent Application Publication
(10) Pub. No.: US 2024/0006466 A1
(43) Pub. Date: Jan. 4, 2024

(54) SHIELDING INTEGRATED INDUCTORS

(71) Applicant: TEXAS INSTRUMENTS INCORPORATED, Dallas, TX (US)

(72) Inventors: Bichoy BAHR, Allen, TX (US); Swaminathan SANKARAN, Allen, TX (US); Benjamin COOK, Los Gatos, CA (US); Baher S. HAROUN, Allen, TX (US)

(21) Appl. No.: 17/855,346

(22) Filed: Jun. 30, 2022

(51) Int. Cl. H01L 49/02; H01F 27/36; H03B 5/32

(52) U.S. Cl. CPC H01L 28/10; H01F 27/36; H03B 5/326

(57) ABSTRACT

An integrated circuit includes a semiconductor substrate, a metal layer, an inductor in the metal layer, and a shield above the inductor. The metal layer is a first metal layer; and the shield may be is in a second metal layer above the first metal layer. The shield may include a plurality of metal strips substantially perpendicular to metal lines of the inductor.

### BACKGROUND

Passive devices, such as inductors, capacitors, and resistors, are commonly used in electronic circuits. Like transistors, passive devices may be fabricated by patterning the various layers (e.g., metal, insulator, etc.) of an integrated circuit. For example, an inductor may be fabricated by etching a metal layer to create a desired inductor pattern. Similarly, a capacitor may be fabricated by etching a metal layer to create the top and bottom plates of the capacitor.

### SUMMARY

In one example, an integrated circuit includes a semiconductor substrate, a metal layer, an inductor in the metal layer, and a shield above the inductor.

In another example, an oscillator circuit includes a bulk acoustic wave (BAW) resonator and an integrated circuit. The integrated circuit is coupled to the BAW resonator, and includes a semiconductor substrate, a metal layer, and a transformer. The transformer is in the metal layer, and includes a winding. The winding is coupled to the BAW resonator and to the oscillator circuit. A shield is above the transformer.

In a further example, a packaged integrated circuit includes a semiconductor substrate, a metal layer, an inductor, a shield, and mold compound. The inductor is in the metal layer. The shield is above the inductor. The mold compound encases the inductor and the shield.

### BRIEF DESCRIPTION OF THE DRAWINGS

FIG. 1 is a cross-sectional view of an example packaged integrated circuit with an integrated inductor and associated electrical and magnetic fields penetrating the package.

FIG. 2 is a cross-sectional view of an example packaged integrated circuit with a patterned shield above an integrated inductor to suppress electrical fields.

FIGS. 3A and 3B are graphs of simulations of the electrical fields about integrated inductors without and with shielding above the inductors.

FIG. 4 is a cross-sectional view of an example packaged integrated circuit including an integrated inductor, and a silicon dummy die attached to the integrated circuit to suppress electric fields.

FIG. 5 is a cross-sectional view of an example packaged integrated circuit including an integrated inductor, and a silicon cap attached to the integrated circuit to suppress electric fields.

FIG. 6 is a cross-sectional view of an example packaged integrated circuit including an integrated inductor, and a silicon glob bonded to the integrated circuit to suppress electric fields.

FIG. 7 is a schematic diagram of an example oscillator circuit that includes a resonator coupled using an integrated transformer.

FIG. 8 is an isometric view of an example transformer and shielding that suppress electric and magnetic fields for use in the oscillator circuit of FIG. 7.

### DETAILED DESCRIPTION

Parasitics of integrated circuit packaging affect inductors and transformers fabricated on the integrated circuit by virtue of the electric and magnetic fields penetrating the package. Dielectric losses, as well as permittivity changes with temperature, humidity, and stress, change the performance of on-chip inductors, making the inductors sensitive to such environmental factors. For example, an oscillator circuit using a microelectromechanical system (MEMS) resonator with on-chip transformer coupling can shift in frequency by 10 s of parts-per-million due to changes in humidity and the moisture content of the plastic integrated circuit packaging. Some integrated circuits include shielding below an inductor to avoid substrate effects, but such shielding provides no protection from effects related the packaging above the inductor.

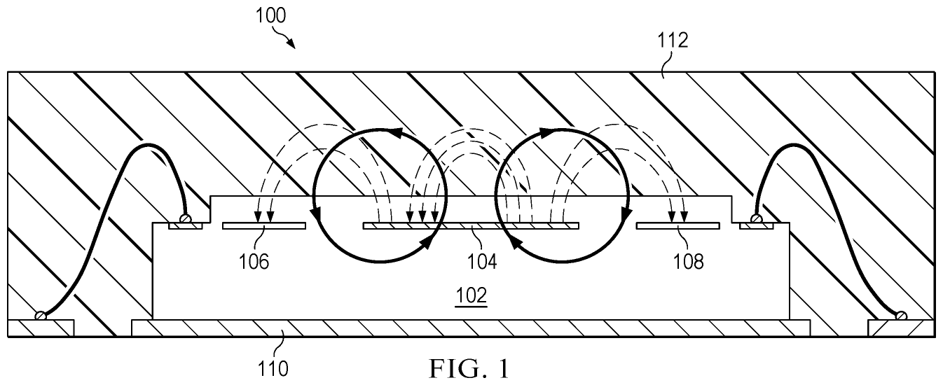

FIG. 1 shows an example packaged integrated circuit 100. The packaged integrated circuit 100 includes an integrated circuit die 102 bonded to a die attach pad 110. The die attach pad 110 may be a metal lead frame. The integrated circuit die 102 includes a semiconductor (e.g., silicon) substrate, an inductor 104 and other circuits 106, 108 formed on the semiconductor substrate. The integrated circuit die 102 includes a metal layer (e.g., a layer of copper), and the inductor 104 is formed as traces patterned in the metal layer. A plastic packaging material 112 (e.g., mold compound) encapsulates the integrated circuit die 102. Electric and magnetic fields pass from the inductor 104, through the plastic packaging material 112, and back to the inductor 104 or the other circuits 106, 108. The dielectric constant of the plastic packaging material 112 changes with changes in humidity, temperature, and/or stress, affecting the performance of the inductor 104.

The integrated circuits of this description include a patterned floating metal shield formed on top of the inductor to terminate the electric fields within the die dielectric stack and prevent the electric fields from penetrating the plastic package. The floating metal shield may be formed in a higher metal interconnect layer, or extra metalization patterned prior to packaging. Some implementations use a dummy high-resistivity silicon die placed atop the inductor, a silicon cap, or a glob of other suitable material atop the inductor to reduce penetration of electric fields into the package molding compound.

In some implementations, an inductor or transformer is implemented as a figure-8, which reduces stray magnetic field, reduces inductor sensitivity to environmental factors, reduces coupling from external circuits, and reduces electromagnetic interference and radiation.

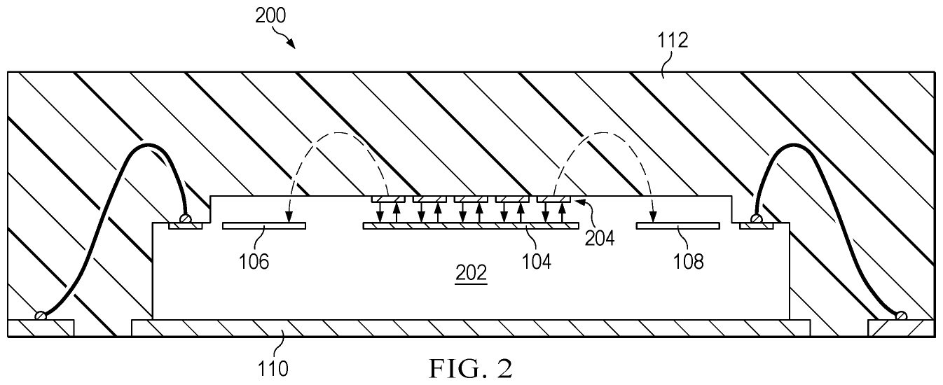

FIG. 2 shows an example packaged integrated circuit 200 configured to reduce the effects of environmental changes on inductor performance. The packaged integrated circuit 200 includes an integrated circuit die 202 bonded to the die attach pad 110. The die attach pad 110 may be a metal lead frame. In some implementations of the packaged integrated circuit 200, the integrated circuit die 202 may not be bonded to a die attach pad. For example, the packaged integrated circuit 200 may be a chip-scale package that lacks lead frame or other interposer. The integrated circuit die 202 includes a semiconductor (e.g., silicon) substrate, an inductor 104 and other circuits 106, 108 formed on the semiconductor substrate. The integrated circuit die 202 includes a metal layer, and the inductor 104 is formed as traces patterned in the metal layer. A plastic packaging material 112 (e.g., mold compound) encapsulates the integrated circuit die 202. The dielectric constant of the plastic packaging material 112 changes with changes in humidity, temperature, and/or stress.

The integrated circuit die 202 also includes a shield 204. The integrated circuit die 202 includes a second metal layer disposed above the metal layer in which the inductor 104 is formed, where “above” refers to a location between the inductor 104 and the plastic packaging material 112. The second metal layer may be a higher metal interconnect layer or extra metalization patterned prior to packaging. The shield 204 may be formed as a set of floating metal strips running perpendicular (substantially perpendicular) to the metal lines of the inductor 104. In the packaged integrated circuit 200, the inter-winding electric field terminates on the shield 204, and penetration of the electric filed into the plastic packaging material 112 is reduced, which reduces the variation in performance of the inductor 104 caused by effects of the environment on the plastic packaging material 112. Selection of shield parameters involves a series of tradeoffs. From a shielding perspective, a solid metal shield, as close as possible to the inductor is preferable. However, such a configuration will introduce substantial eddy currents in the shield, degrade the quality factor of the inductor significantly, and introduce considerable capacitive loading on the inductor. The shield may be broken into strips to prevent the eddy currents from flowing and positioned as far from the inductor as the process would allow to reduce capacitive loading.

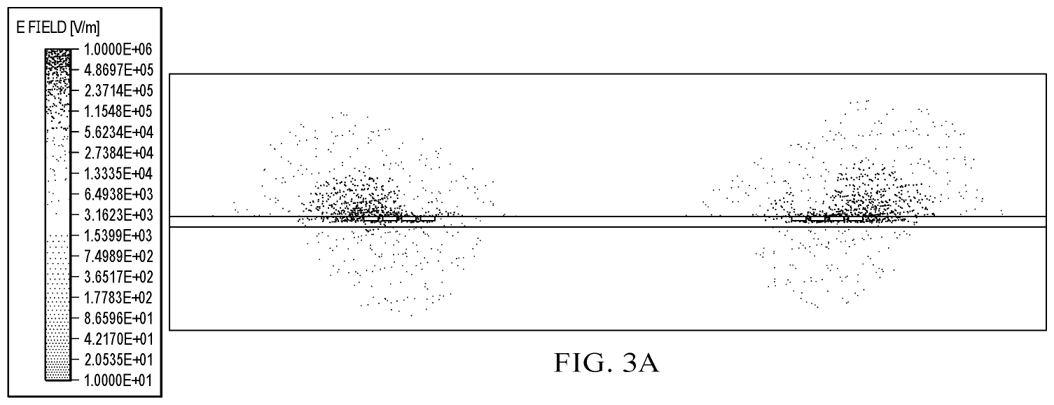

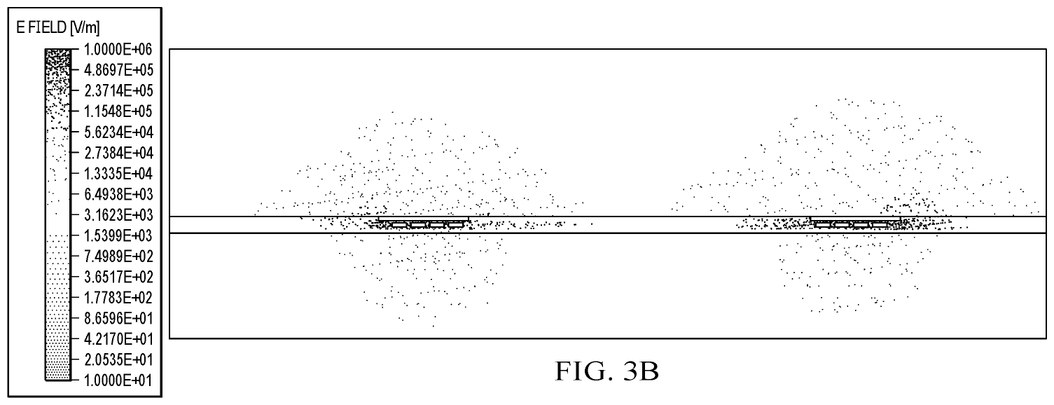

FIGS. 3A and 3B show simulations of the electrical fields about integrated inductors without and with shielding above the inductors. FIG. 3A shows the electric fields in a packaged integrated circuit that lacks shielding above the inductors. FIG. 3B shows the electric fields in a packaged integrated circuit that includes shielding above the inductors. The electric field propagation in FIG. 3A (without shielding) is significantly greater (in magnitude and penetration depth) than in FIG. 3B (with shielding). Thus, the inclusion of the shield 204 effectively terminates the electric field emanating from the inductor 104.

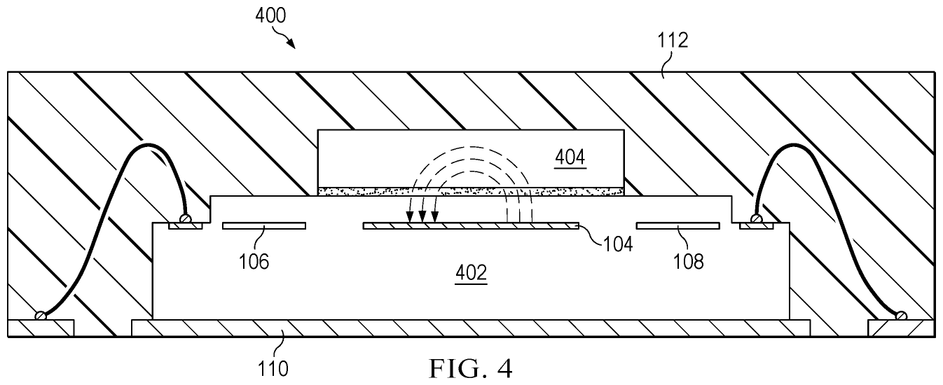

FIG. 4 shows an example packaged integrated circuit 400 configured to reduce the effects of environmental changes on inductor performance. The packaged integrated circuit 400 includes an integrated circuit die 402 bonded to the die attach pad 110. The die attach pad 110 may be a metal lead frame. In some implementations of the packaged integrated circuit 400, the integrated circuit die 402 may not be bonded to the die attach pad 110. For example, the packaged integrated circuit 400 may be a chip-scale package that lacks lead frame or other interposer. The integrated circuit die 402 includes a semiconductor (e.g., silicon) substrate, an inductor 104 and other circuits 106, 108 formed on the semiconductor substrate. The integrated circuit die 402 includes a metal layer, and the inductor 104 is formed as traces patterned in the metal layer. A plastic packaging material 112 (e.g., mold compound) encapsulates the integrated circuit die 402. The dielectric constant of the plastic packaging material 112 changes with changes in humidity, temperature, and/or stress.

A dummy die 404 is bonded to the integrated circuit die 402 above the inductor 104. The dummy die 404 may be formed of silicon (e.g., high resistivity silicon) or any other material that inhibits permeation of moisture, and has low electric losses (small dielectric loss tangent). During fabrication of the packaged integrated circuit 400, an instance of the dummy die 404 can be picked and placed on individual instances of the integrated circuit die 402. Wafer level encapsulation may be applied to encase the integrated circuit die 402 and the dummy die 404 in the plastic packaging material 112. In the packaged integrated circuit 400, the dummy die 404 prevents or reduces penetration of the inter-winding electric field into the plastic packaging material 112.

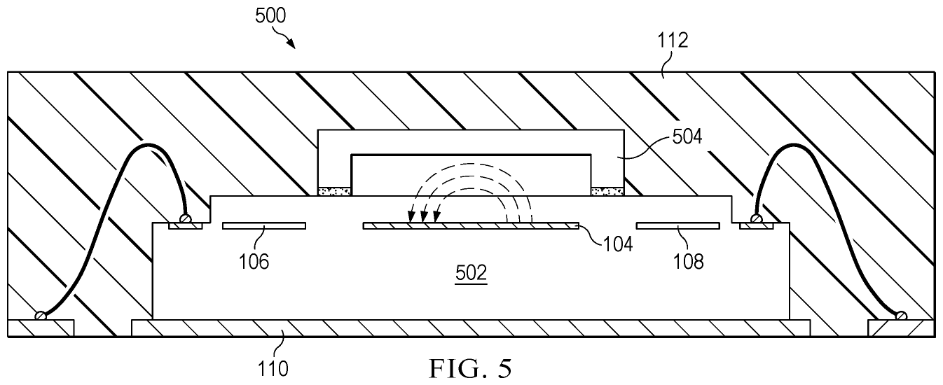

FIG. 5 shows an example packaged integrated circuit 500 configured to reduce the effects of environmental changes on inductor performance. The packaged integrated circuit 500 includes an integrated circuit die 502 bonded to the die attach pad 110. The die attach pad 110 may be a metal lead frame. In some implementations of the packaged integrated circuit 500, the integrated circuit die 502 may not be bonded to the die attach pad 110. For example, the packaged integrated circuit 500 may be a chip-scale package that lacks lead frame or other interposer. The integrated circuit die 502 includes a semiconductor (e.g., silicon) substrate, an inductor 104 and other circuits 106, 108 formed on the semiconductor substrate. The integrated circuit die 502 includes a metal layer, and the inductor 104 is formed as traces patterned in the metal layer. A plastic packaging material 112 (e.g., mold compound) encapsulates the integrated circuit die 502. The dielectric constant of the plastic packaging material 112 changes with changes in humidity, temperature, and/or stress.

A cap 504 is bonded to the integrated circuit die 402 above the inductor 104. The cap 504 may be formed of silicon or any other material that inhibits permeation of moisture. During fabrication of the packaged integrated circuit 500, an instance of the cap 504 can be picked and placed on individual instances of the integrated circuit die 502. In the packaged integrated circuit 500, the cap 504 prevents or reduces penetration of the inter-winding electric field into the plastic packaging material 112.

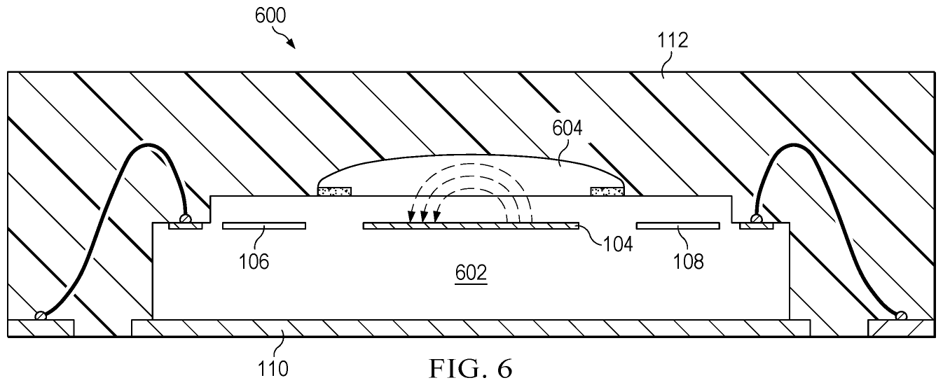

FIG. 6 shows an example packaged integrated circuit 600 configured to reduce the effects of environmental changes on inductor performance. The packaged integrated circuit 600 includes an integrated circuit die 602 bonded to the die attach pad 110. The die attach pad 110 may be a metal lead frame. In some implementations of the packaged integrated circuit 600, the integrated circuit die 602 may not be bonded to the die attach pad 110. For example, the packaged integrated circuit 600 may be a chip-scale package that lacks lead frame or other interposer. The integrated circuit die 602 includes a semiconductor (e.g., silicon) substrate, an inductor 104 and other circuits 106, 108 formed on the semiconductor substrate. The integrated circuit die 602 includes a metal layer, and the inductor 104 is formed as traces patterned in the metal layer. A plastic packaging material 112 (e.g., mold compound) encapsulates the integrated circuit die 602. The dielectric constant of the plastic packaging material 112 changes with changes in humidity, temperature, and/or stress.

A glob 604 of material is bonded to the integrated circuit die 602 above the inductor 104. The glob 604 may be formed of silicon or any other material that doesn't allow permeation of moisture. During fabrication of the packaged integrated circuit 600, an instance of the glob 604 can be deposited on individual instances of the integrated circuit die 602. In the packaged integrated circuit 600, the glob 604 prevents or reduces penetration of the inter-winding electric field into the plastic packaging material 112.

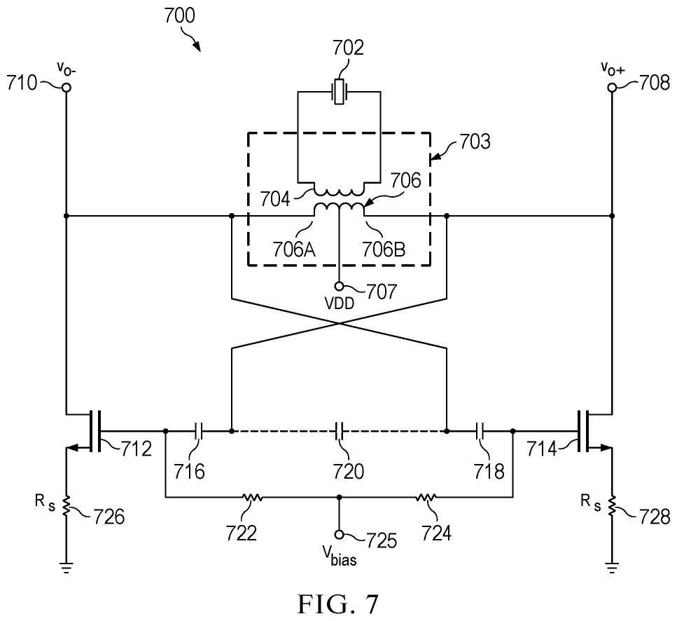

FIG. 7 shows an example oscillator circuit 700 that includes an integrated transformer. The oscillator circuit 700 includes a BAW resonator 702, a transformer 703, a transistor 712, a transistor 714, a capacitor 716, a capacitor 718, a capacitor 720, a resistor 722, a resistor 724, a resistor 726, and a resistor 728. The transformer 703 includes an inductor 704 (a first coil) and an inductor 706 (a second coil). The BAW resonator 702 is coupled to the inductor 704. The inductor 706 is coupled to the transistor 712 and the transistor 714, and is magnetically coupled to the inductor 704 to form the transformer 703. The inductor 706 includes a center tap terminal 707 that is coupled to a power supply voltage in some implementations. A drain of the transistor 712 is coupled to a terminal 706A of the inductor 706 and to an output 710. A drain of the transistor 714 is coupled to a terminal 706B of the inductor 706 and to an output 708. The source of the transistor 712 is coupled to ground via the resistor 726, and the source of the transistor 714 is coupled to ground via the resistor 728. The gate of the transistor 712 is coupled to the terminal 706B of the inductor 706 via the capacitor 716, and the gate of the transistor 714 is coupled to the terminal 706A via the capacitor 718. In some implementations, the capacitor 716 is coupled to the capacitor 718 via the capacitor 720. The gate of the transistor 712 is coupled to a bias voltage terminal 725 via the resistor 722, and the gate of the transistor 714 is coupled to the bias voltage terminal 725 via the resistor 724.

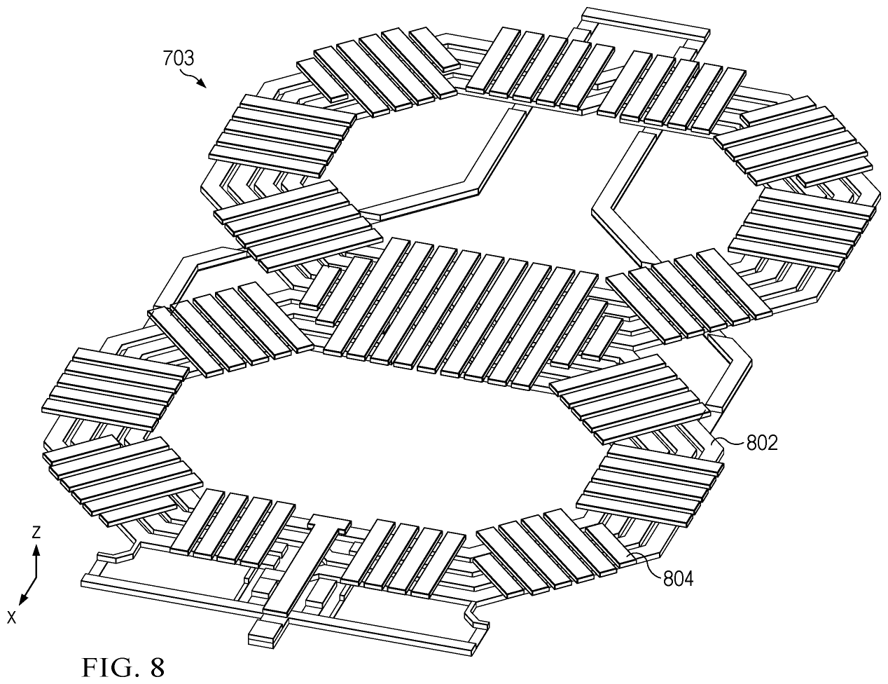

The oscillator circuit 700 may be implemented with shielding above the transformer 703 as shown in the packaged integrated circuit 200, the packaged integrated circuit 400, the packaged integrated circuit 500, and the packaged integrated circuit 600 to improve the stability of the oscillator with changes in the environment (e.g., humidity, temperature, and stress). FIG. 8 shows an example transformer 703 suitable for use in the oscillator circuit 700. A shield disposed above the transformer 703 suppresses electrical fields emanating from the transformer 703. The transformer 703 is a figure-8 transformer to reduce the magnetic field emanated. The transformer 703 may be constructed using multiple metal layers of an integrated circuit. The transformer 703 includes windings 802 formed as a figure-8 in the metal layers of an integrated circuit. A shield is formed by the metal strips 804, which are patterned in a metal layer above the highest metal layer of the windings 802. The metal strips 804 are arranged to be orthogonal to the underlying traces of the windings 802.

In this description, the term “couple” or “couples” may cover connections, communications, or signal paths that enable a functional relationship consistent with this description. For example, if device A generates a signal to control device B to perform an action: (a) in a first example, device A is coupled to device B; or (b) in a second example, device A is coupled to device B through intervening component C if intervening component C does not alter the functional relationship between device A and device B, such that device B is controlled by device A via the control signal generated by device A. Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

While the use of particular transistors is described herein, other transistors (or equivalent devices) may be used instead. For example, a p-channel field effect transistor (“PFET”) may be used in place of an n-channel field effect transistor (“NFET”) with little or no changes to the circuit. Furthermore, other types of transistors may be used (such as bipolar junction transistors (BJTs)).

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

Circuits described herein are reconfigurable to include additional or different components to provide functionality at least partially similar to functionality available prior to the component replacement. Components shown as transistors, unless otherwise stated, are generally representative of any one or more transistors coupled in parallel to provide desired channel width or emitter size.

In this description, unless otherwise stated, “about,” “approximately” or “substantially” preceding a parameter means being within +/−10 percent of that parameter.

Modifications are possible in the described embodiments, and other embodiments are possible, within the scope of the claims.

What is claimed is:

1. An integrated circuit, comprising:
a semiconductor substrate;
a metal layer;
an inductor in the metal layer; and
a shield above the inductor.

2. The integrated circuit of claim 1, wherein:
the metal layer is a first metal layer; and
the shield is in a second metal layer above the first metal layer.

3. The integrated circuit of claim 1, wherein the shield includes a plurality of metal strips substantially perpendicular to metal lines of the inductor.

4. The integrated circuit of claim 1, wherein the shield includes a silicon dummy die above the inductor.

5. The integrated circuit of claim 1, wherein the shield includes a cap above the inductor.

6. The integrated circuit of claim 5, wherein the cap is a silicon cap.

7. The integrated circuit of claim 1, wherein the shield includes a silicon glob above the inductor.

8. The integrated circuit of claim 1, wherein the inductor is a figure-8 inductor.

9. An oscillator circuit, comprising:
a bulk acoustic wave (BAW) resonator;
an integrated circuit coupled to the BAW resonator, and including:
a semiconductor substrate;
a metal layer;
a transformer in the metal layer including:
a winding coupled to the BAW resonator and the oscillator circuit; and
a shield above the transformer.

10. The oscillator circuit of claim 9, wherein:
the metal layer is a first metal layer; and
the shield is in a second metal layer above the first metal layer.

11. The oscillator circuit of claim 9, wherein the shield includes a plurality of metal strips substantially perpendicular to metal lines of the winding.

12. The oscillator circuit of claim 9, wherein the shield includes a silicon dummy die above the transformer.

13. The oscillator circuit of claim 12, wherein the shield includes a cap above the transformer.

14. The oscillator circuit of claim 9, wherein the shield includes a silicon glob above the transformer.

15. The oscillator circuit of claim 9, wherein the transformer is a figure-8 transformer.

16. A packaged integrated circuit, comprising:
a semiconductor substrate;
a metal layer;
an inductor in the metal layer;
a shield above the inductor; and
a mold compound encasing the inductor and the shield.

17. The packaged integrated circuit of claim 16, wherein:
the metal layer is a first metal layer;
the shield is in a second metal layer above the first metal layer; and
the shield includes a plurality of metal strips substantially perpendicular to metal lines of the inductor.

18. The packaged integrated circuit of claim 16, wherein the shield includes a silicon dummy die above the inductor.

19. The packaged integrated circuit of claim 16, wherein the shield includes a cap above the inductor.

20. The packaged integrated circuit of claim 16, wherein the shield includes a silicon glob above the inductor.
